(19) United States
(12) Patent Application Publication
(10) Pub. No.: US 2024/0130237 A1
(43) Pub. Date: Apr. 18, 2024

(54) METHOD FOR METALLISING A THERMOELECTRIC STRUCTURE

(71) Applicant: COMMISSARIAT À L'ÉNERGIE ATOMIQUE ET AUX ÉNERGIES ALTERNATIVES, Paris (FR)

(72) Inventors: Guillaume Savelli, Grenoble (FR); Maxime Baudry, Grenoble (FR); Guilhem Roux, Grenoble (FR)

(21) Appl. No.: 18/485,471

(22) Filed: Oct. 12, 2023

(30) Foreign Application Priority Data
Oct. 14, 2022 (FR) 2210614

(51) Int. Cl. H10N 10/01

(52) U.S. Cl. CPC H10N 10/01

(57) ABSTRACT

A method for manufacturing a thermoelectric structure including the following steps: a) providing a substrate, covered with a metal layer, b) forming a thermoelectric element on the metal layer, by additive manufacturing, preferably by SLS or PBF, and c) optionally removing the substrate, by means of which a thermoelectric structure, which comprises the metal layer and the thermoelectric element, is obtained.

### CROSS-REFERENCE TO RELATED APPLICATIONS

This application claims priority from French Patent Application No. 2210614 filed on Oct. 14, 2022. The content of this application is incorporated herein by reference in its entirety.

### TECHNICAL FIELD

The present invention relates to the general field of thermoelectric modules.

The invention relates to a method for manufacturing thermoelectric structures.

The invention also relates to a thermoelectric structure obtained by such a method.

The invention also relates to thermoelectric devices comprising two thermoelectric structures thus obtained, one being with a first conductivity type and the other being with a second conductivity type.

The invention finds applications in numerous industrial fields, and in particular for applications needing thermoelectric generators, where a thermal gradient is available (e.g. transport, industry, etc.), radioisotope thermoelectric generator applications, Peltier applications or thermal sensor applications.

The invention is particularly interesting since it makes it possible to form thermoelectric structures/devices having low resistivities.

### PRIOR ART

Generally, thermoelectric (TE) modules comprise a set of first pins made from a thermoelectric material with a first conductivity type and a set of second pins made from a piezoelectric material with a second conductivity type. For example, the first material is an N-type material (i.e. with N-type conductivity) and the second material is a P-type material (i.e. with P-type conductivity).

The pins are connected electrically in series and thermally in parallel. The pins are connected together by metal elements. The thermoelectric junctions are also referred to as NP junctions. The pins are held by ceramic substrates disposed on either side of the pin assemblies.

The electrical performances of a TE device in generator mode are given by:
an internal electrical resistance Rᵢₙₜ defined according to (1):

Rᵢₙₜ=N×ρₙₚ×L/A+R_{c}+Rₘₑₜ (1)
with N the number of NP junctions, ρₙₚ the electrical resistivity of the NP materials, L the length of a line or thickness of a pin, A the cross section of a line or of a pin, R_{c} the total resistance of the contacts and Rₘₑₜ the total resistance of the metal junctions
a useful electric power Pu defined according to (2):

Pu=V_{oc}²/4Rᵢₙₜ
with V_{oc} the voltage generated by the TE module.

Thus, to have high power, it is necessary to have a low internal electrical resistance, and therefore to reduce the contribution of the total resistance of the contacts R_{c} and of the total resistance of the metal junctions Rₘₑₜ.

Conventionally, TE modules are generally manufactured using the following steps: manufacture of the TE materials (sintering), formation of the pins, metallisation of the pins, assembly with the substrates.

The metal connections are made directly on the substrates, for example by the so-called direct-copper technique (or DBC, standing for “direct bonding copper”), and then brazing and pressing with the pins.

However, this manufacturing method is relatively complex and greatly limits the geometry and modularity of the manufactured thermoelectric device.

There are also TE modules without substrate, also referred to as “skeleton modules”. These modules therefore do not have any heat loss due to the substrates. However, they cannot be in contact with electrically conductive surfaces.

It is also possible to use TE pins produced from several TE materials. These so-called segmented pins make it possible to accommodate a greater temperature difference at the ends of the module since the materials used are generally optimised for different temperature ranges.

### DESCRIPTION OF THE INVENTION

One aim of the present invention is to propose a method for manufacturing thermoelectric structures that is simple to implement and makes it possible to manufacture thermoelectric structures having good electrical properties (in particular low contact resistance) and/or good thermal properties.

For this purpose, the present invention proposes a method for manufacturing a thermoelectric structure comprising the following steps:
providing a substrate, covered completely or locally, with a metal layer,
b) forming a thermoelectric element made from a thermoelectric material on the metal layer, by additive manufacturing, preferably by SLS or PBF, by means of which a thermoelectric structure, which comprises the substrate covered successively by the metal layer and by the thermoelectric element, is obtained.

The invention is fundamentally distinguished from the prior art by the implementation of a step during which the functionalisation (metallisation) of the thermoelectric element (for example a thermoelectric pin) is implemented during the additive manufacturing method.

This leads not only to an appreciable reduction in the number of steps and therefore to a simplification of the method compared with the methods of the prior art, but also to a considerable saving in time and a reduction in costs.

The metallisation obtained has good mechanical strength and good electrical and/or thermal conduction properties.

Preferably, the additive manufacturing technique is a laser powder bed fusion (PBF for Powder Bed Fusion) technique or a selective laser sintering (SLS) technique.

Advantageously, the method includes a subsequent step c) during which the substrate is removed, by means of which a thermoelectric structure, which comprises the metal layer and the thermoelectric element, is obtained.

Advantageously, the thermoelectric element is a part in the form of a comb delimiting a base and a plurality of arms, substantially parallel to each other, extending substantially orthogonally from the base, the plurality of arms having a first end and a second end, the first end being connected to the base, and the second end of the plurality of arms being in contact with the metal layer.

Advantageously, the thermoelectric element is a pin, having a base and a height.

According to this advantageous variant, the metal layer may have the same surface area as the surface area of the base of the pin. Still according to this advantageous variant, the metal layer may have a surface area greater than the surface area of the base of the pin.

Advantageously, in step a), the metal layer locally covers the substrate so as to form a plurality of islands and a thermoelectric element or a plurality of thermoelectric elements are deposited on each island during step b).

Advantageously, the thermoelectric material is Si, SiGe, Bi₂Te₃, Half-Heusler or Skutterudites.

Advantageously, the substrate is 316L steel, aluminium, titanium, a CuZr alloy, a ceramic or graphite.

Advantageously, the metal layer is made from a material selected from Al, Ti, Cu, Au and Ni.

The method has numerous advantages:
it has a small number of steps,
it is simple and economical,
it allows great modularity of form and design of the thermoelectric device manufactured,
the pins can have complex forms.

The invention also relates to a thermoelectric structure obtained by such a method, comprising successively:
optionally a substrate,
a metal layer, for example made from Al, Ti, Cu, Au or Ni,
one or more thermoelectric elements, preferably pins, disposed on the metal layer.

The invention also relates to a thermoelectric device comprising two thermoelectric structures, as defined previously, each structure comprising:
optionally a substrate,
a metal layer, for example made from Al, Ti, Cu, Au or Ni,
one or more thermoelectric elements, preferably pins,
the thermoelectric element or elements of one of the thermoelectric structures being of a first conductivity type and the thermoelectric element or elements of the other thermoelectric structure being of a second conductivity type opposite to the first conductivity type.

Other features and advantages of the invention will become apparent from the following additional description.

It goes without saying that this additional description is given only as an illustration of the object of the invention and should in no way be interpreted as a limitation of this object.

### BRIEF DESCRIPTION OF THE DRAWINGS

The present invention will be better understood upon reading the description of embodiments given merely for indication and without limitation with reference to the appended drawings wherein:

FIG. 1A, FIG. 1B and FIG. 1C show, schematically and in cross-section, the various steps of a method for manufacturing a thermoelectric structure according to a first embodiment of the invention.

FIG. 2A, FIG. 2B, FIG. 2C and FIG. 2D show, schematically and in cross-section, the various steps of a method for manufacturing a thermoelectric device according to a second embodiment of the invention.

FIG. 3A, FIG. 3B, FIG. 3C, FIG. 3D and FIG. 3E show, schematically and in cross-section, the various steps of a method for manufacturing a thermoelectric device according to a third embodiment of the invention.

FIG. 4A, FIG. 4B, FIG. 4C and FIG. 4D show, schematically and in cross-section, the various steps of a method for manufacturing a thermoelectric device according to a fourth embodiment of the invention.

FIG. 5A, FIG. 5B and FIG. 5C show, schematically and in cross-section, the various steps of a method for manufacturing a thermoelectric structure according to a fifth embodiment of the invention.

FIG. 6A, FIG. 6B, FIG. 6C and FIG. 6D show, schematically and in cross-section, the various steps of a method for manufacturing a thermoelectric structure according to a sixth embodiment of the invention.

The different parts shown in the figures are not necessarily plotted according to a uniform scale, to make the figures more readable.

The various possibilities (alternatives and embodiments) must be understood as not being mutually exclusive and can be combined with one another.

Moreover, in the description below, the terms that depend on the orientation, such as “above”, “below”, etc. of a structure apply for a structure that is considered to be oriented in the manner illustrated in the figures.

### DETAILED DESCRIPTION OF SPECIFIC EMBODIMENTS

Although this is in no way limitative, the invention is particularly interesting for applications needing thermoelectric generators (TEG, standing for “ThermoElectric Generator”), where a thermal gradient is available (e.g. transport, industry, etc.), radioisotope thermoelectric generator applications (RTG, standing for “Radioisotope Thermoelectric Generators”) in particular for SiGe, Peltier applications or thermal sensor applications.

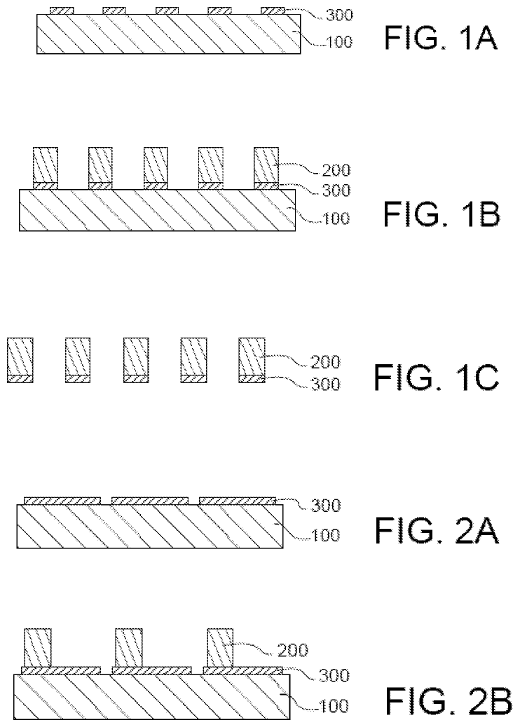

As shown in FIG. 1A to 1C, 2A to 2B, 3A to 3C, 4A to 4B, 5A to 5C, 6A to 6D, the method for manufacturing a thermoelectric structure comprises the following steps:
providing a substrate 100, covered completely or locally, with a metal layer 300,
b) forming a thermoelectric element 200 made from a thermoelectric material, on the metal layer 300, by additive manufacturing, preferably by SLS or PBF, by means of which a thermoelectric structure, which comprises the substrate 100 covered successively by the metal layer 300 and by the thermoelectric element (200), is obtained,
c) optionally, removing the substrate 100, by means of which a thermoelectric structure, which comprises the metal layer 300 and the thermoelectric element (200), is obtained.

The substrate 100 provided at step a) may be a plate or an overplate.

In additive manufacturing machines, the overplates are attached directly to the plates, and make it possible not only to obtain finer thicknesses (between 200 μm and a few millimetres), but also to increase the nature of the materials that can be used. The overplate is advantageously made from ceramic.

The substrate 100 is for example made from a metal (for example Al, Ti, Cu, Au or Ni), from a metal alloy, from a semiconductor material, from ceramic or from graphite. For example, it is made from 316L steel, aluminium, titanium, CuZr, ceramic or graphite.

The substrate 100 can have a thickness ranging from a few hundreds of micrometres to a few centimetres and, preferably, from a few hundreds of micrometres to a few millimetres.

The substrate 100 provided at step a) is covered with a metal layer 300 (also referred to as a bonding layer) made from a third material.

The bonding layer 300 may be deposited for example by physical vapour deposition (PVD), by evaporation or by sputtering.

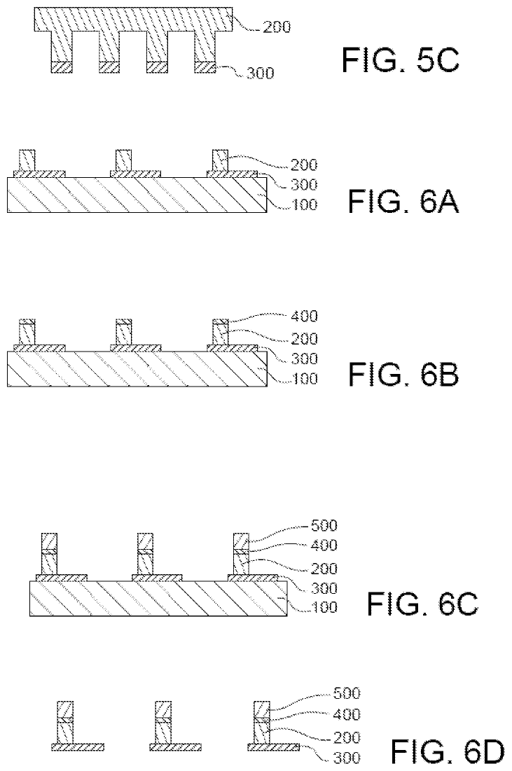

The bonding layer 300 can cover the substrate 100 locally (FIG. 1A, 2A, 3A, 4A, 6A) or completely (FIG. 5A). For example, the metal bonding layer 300 forms islands on the surface of the substrate 100.

To obtain a metal layer 300 covering the substrate 100 locally, it is possible to implement a localised deposition of this layer. Alternatively, it is possible to implement a full deposition of a continuous layer followed by a step during which part of the continuous layer is removed, for example by etching, to form the islands.

The bonding layer 300 is made from a material different from that of the substrate 100.

The bonding layer 300 is, for example, made from metal or from a metal alloy. Preferably, the metal is selected from Al, Ti, Cu, Au and Ni. Several layers can be superimposed, for example, it may be a dual layer or a triple layer. A triple layer formed from a layer of copper, from a layer of nickel and from a layer of gold can be selected. By way of illustration and non-limitatively, it is possible to select a triple layer formed from Cu (for example 200 nm)+Ni (for example 5 μm)+Au (for example 10 nm).

After the formation of the bonding layer 300, an annealing step may be implemented.

During step b), the thermoelectric element 200 is formed on the metal bonding layer 300. It is directly in contact with this bonding layer 300.

The thermoelectric element 200 is made from a second material. The second material is preferably selected from Si, SiGe, MnSi, Bi₂Te₃, Half-Heusler and Skutterudites. Skutterudites are mineral species composed of cobalt and nickel arsenide of formula (Co, Ni)As₃₋ₓ with traces of S, Bi, Cu, Pb, Zn, Ag, Fe and Ni.

The thermoelectric element 200 can have N-type conductivity to favour the movement of the electrons (i.e. the material that makes it up has a strictly negative Seebeck coefficient) or P-type conductivity to favour the movement of the holes (i.e. the material that makes it up has a strictly positive Seebeck coefficient).

For example, the N-type doped thermoelectric material is a silicon-germanium (SiGe) alloy doped by phosphorus or N-type doped polysilicon. The N-type dopant can be phosphorus or arsenic.

For example, the P-type doped material is a silicon-germanium (SiGe) alloy doped by boron or P-type doped polysilicon. The P-type dopant is preferentially boron.

Advantageously, the dopant is directly integrated in the base powder.

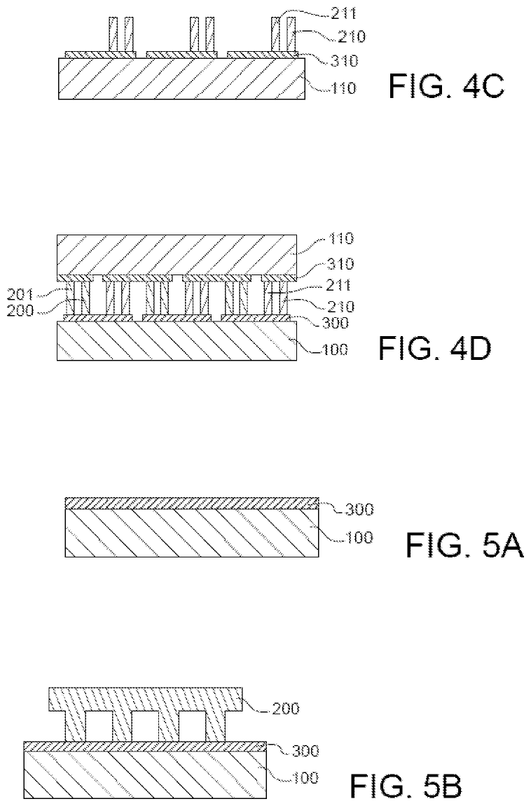

A thermoelectric element 200 (FIG. 1B, 2B, 3B, 6B) or a plurality of thermoelectric elements 200, 201 can be formed on each island (FIG. 4B).

The thermoelectric element 200 deposited at step b) is obtained by additive manufacturing. The method consists in depositing the material in several successive passes on the bonding layer 300. At the end of successive depositions, the thermoelectric element is obtained. The substrate may be a plate or an overplate.

Preferably, the additive manufacturing technique is a powder bed laser fusion (PBF) technique or a selective laser sintering (SLS) technique.

The PBF methods consist in melting certain regions of a powder bed, for example by means of a laser beam.

In the SLS method, the powders are sintered. The materials of the powders do not go into the liquid phase.

However, other additive manufacturing techniques can be envisaged, such as cold spray, electron beam melting, etc.

The thermoelectric element 200 deposited at step b) can take several forms.

According to a first advantageous variant embodiment, the thermoelectric element 200 is a part in the form of a comb (FIG. 5B).

The part is in the form of a comb delimiting a base and a plurality of arms, substantially parallel to each other, extending substantially orthogonally from the base. The plurality of arms have a first end and a second end. The first end is connected to the base, and the second end is in contact with the metal bonding layer 300.

“Substantially orthogonal” means “orthogonal” or “orthogonal to within plus or minus 10° of tolerance”.

“Substantially parallel” means “parallel” or “parallel to within plus or minus 10° of tolerance”.

According to another variant embodiment, the thermoelectric element 200 is a pin (FIG. 1B, 2B, 3B, 4B, 6A). The pin has a base having a surface and a height.

The metal layer 300 may have the same surface area as the surface area of the base of the pin or of the second end of the arms of the comb.

The metal layer 300 may have a surface area greater than the surface area of the base of the pin. Highly advantageously, in step b), a plurality of pins 200, 201 are deposited on the metal layer 300 (FIG. 4B).

At the end of step b), a thermoelectric structure, which comprises a substrate 100, a bonding layer 300, continuous or discontinuous, for example in the form of islands, on which one or more thermoelectric elements 200 are formed, is obtained.

After step b), a thermal annealing can be implemented.

Advantageously, between step b) and step c), the method comprises an additional step during which an intermediate metallisation layer 400 (FIG. 6B) and then an additional thermoelectric element 500 made from a fourth material (FIG. 6C) are deposited on the thermoelectric element 200. The fourth material is different from the second material.

During step c), the substrate 100 is removed.

The substrate 100 can be removed by laser cutting, water jet, wire saw, etc.

At the end of step c), a thermoelectric structure, which comprises a metal bonding layer 300 on which one or more thermoelectric elements 200 are formed, is obtained.

Thus, at the end of step b) or of step c), a first thermoelectric structure is thus obtained.

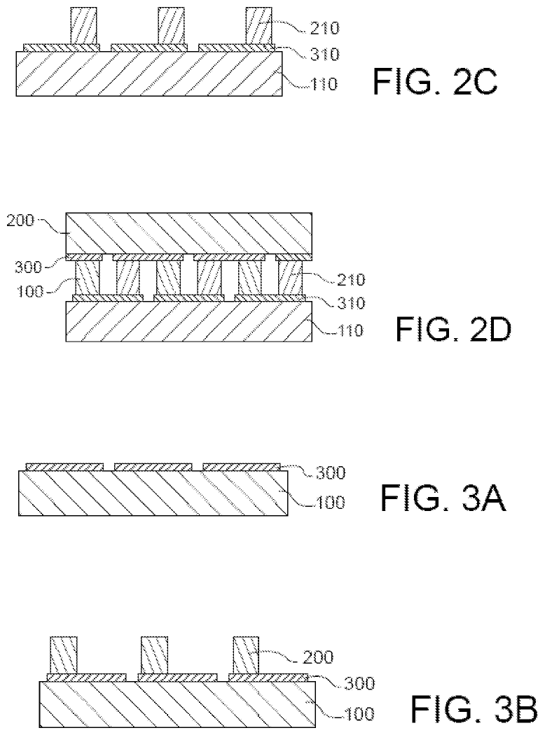

Advantageously, the previously described manufacturing method is used to manufacture a second thermoelectric structure (FIGS. 2C, 3D and 4C).

The second structure comprises successively a substrate 110, a metal layer 310 and one or more thermoelectric elements 210, 211 (FIGS. 2C, 4C). The thermoelectric material of the second structure has a doping different from that of the first structure.

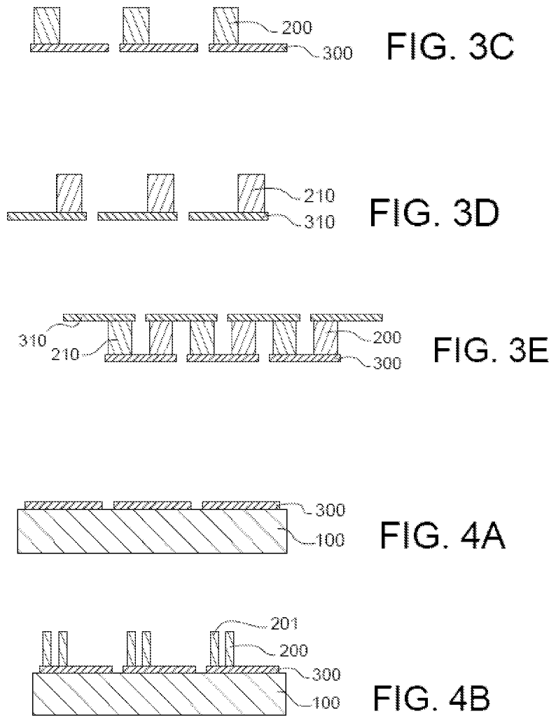

The substrate 110 can be removed to have a thermoelectric structure comprising a metal layer 310 and one or more thermoelectric elements 210, 211 (FIG. 3D).

The two structures obtained are advantageously assembled and electrically connected to form a thermoelectric device (FIGS. 2D, 3E and 4D).

It is possible to connect the devices in series and/or in parallel. It is advantageous to combine series connections and parallel connections in order to optimise the output electrical performances of the thermoelectric device manufactured.

The materials of the metal layers 300, 310 of the two structures may be identical or different. The materials of the substrates 100, 110 used may be identical or different.

The invention is particularly advantageous for manufacturing conventional thermoelectric modules, DBC substrates, so-called skeleton thermoelectric modules or segmented thermoelectric pins.

The thermoelectric device obtained can operate in Seebeck mode (i.e. the thermoelectric device is then an electrical energy generator) or in Peltier mode (i.e. the thermoelectric device is then a thermal energy generator).

Various embodiments will now be described in more detail with reference to the accompanying figures.

According to a first embodiment shown in FIG. 1A to 1C, the method comprises the following steps:
providing a substrate 100 made from a first material, locally covered with a metal layer 300 forming islands made from a third material,
b) depositing a thermoelectric pin 200 made from a second material on each island of the metal layer 300, by additive manufacturing, preferably by SLS or PBF, the surface area of the base of the pins advantageously being of the same size as the surface area of the islands,
c) removing the substrate 100, by means of which a thermoelectric structure, which comprises thermoelectric pins 200 covered by a metal layer 300, is obtained.

This first embodiment is advantageous since it makes it possible to simply metallise the pins by depositing a metal layer 300 on the plate of the additive manufacturing machine.

According to a second embodiment shown in FIG. 2A to 2D, the method comprises the following steps:
providing a substrate 100 made from a first material, locally covered with a metal layer 300 forming islands made from a third material,
b) depositing a thermoelectric pin 200 made from a second material on each island of the metal layer 300, by additive manufacturing, preferably by SLS or PBF, the surface area of the base of the pins advantageously being smaller than the surface area of the islands, by means of which a first thermoelectric structure, which comprises a substrate 100 locally covered by a metal layer 300 forming islands, a thermoelectric pin 200 being disposed on each island, is obtained
d) repeating steps a) and b) to form a second thermoelectric structure comprising a substrate 110 locally covered by a metal layer 310 forming islands, each island being covered by a thermoelectric pin 210, the thermoelectric material of the thermoelectric pins of the second structure having a conductivity opposite to that of the second material of the first structure (FIG. 2C),
e) assembling and electrically connecting the first thermoelectric structure and the second thermoelectric structure (FIG. 2D).

This second embodiment is advantageous since it also makes it possible to produce skeleton modules.

According to a third embodiment shown in FIG. 3A to 3E, the method comprises the following steps:
providing a substrate 100 made from a first material, locally covered with a metal layer 300 forming islands made from a third material,
b) depositing a thermoelectric pin 200 made from a second material on each island of the metal layer 300, by additive manufacturing, preferably by SLS or PBF, the surface area of the base of the pins advantageously being smaller than the surface area of the islands,
c) removing the substrate 100, by means of which a thermoelectric structure, which comprises thermoelectric pins 200 covered by a metal layer 300, is obtained,
d) repeating steps a) to c) to form a second thermoelectric structure (FIG. 3D),
e) assembling and electrically connecting the first thermoelectric structure and the second thermoelectric structure (FIG. 3E).

More particularly, step d) thus comprises the following steps:
providing a substrate 110 made from a material that may be identical to or different from that of the substrate 100 of the first structure, the substrate 110 being locally covered with a metal layer 310 forming islands,
depositing a thermoelectric pin 210 made from a fourth material on each island of the metal layer 310, by additive manufacturing, preferably by SLS or PBF, the surface area of the base of the pins advantageously being smaller than the surface area of the islands, the pins of the second structure being made from a thermoelectric material with a conductivity opposite to the conductivity of the thermoelectric material of the first thermoelectric structure,
removing the substrate 110, by means of which a thermoelectric structure, which comprises thermoelectric pins 210, 211 covered by a metal layer 310, is obtained.

According to this third embodiment, it is possible thus to form skeleton modules (FIG. 3E).

According to a fourth embodiment shown in FIG. 4A to 4D, the method comprises the following steps:
providing a substrate 100 made from a first material, locally covered with a metal layer 300 made from a third material, forming islands,
b) depositing a plurality of thermoelectric pins 200, 201 made from a second material on each island of the metal bonding layer 300, by additive manufacturing, preferably by SLS or PBF, by means of which a structure, which comprises a substrate 100 made from a first material covered by a metal layer 300 forming islands, on which a plurality of thermoelectric pins 200, 201 are disposed, is obtained.

The same method is used for manufacturing an additional structure comprising a substrate 110, locally covered by a metal layer 310 forming islands on which a plurality of thermoelectric pins 210, 211 are formed by additive manufacturing (FIG. 4C). The thermoelectric pins 210, 211 of the second structure have a conductivity opposite to the conductivity of the pins 200, 210 of the first structure. The substrates 100, 110 of the two structures are advantageously ceramic overplates, having for example a thickness of between 200 μm and a few millimetres (for example 3 millimetres).

The two structures are next assembled (FIG. 4D).

This fourth embodiment is particularly advantageous since it makes it possible to combine series/parallel connections and thus to optimise the output electrical performances. This is because it is possible to electrically connect the various thermoelectric pins as needed. Usually, all the pins are electrically connected in series. But this may lead to obtaining high output voltages (of several volts), which is incompatible with associated electronics (“power management unit”), for which the voltages are generally of a few volts. This embodiment makes it possible to connect some pins in parallel while decreasing the output voltage, and while maintaining the generated power.

According to a fifth embodiment shown in FIG. 5A to 5C, the method comprises the following steps:
providing a substrate 100 made from a first material, covered with a metal bonding layer 300 made from a third material,
b) forming a thermoelectric part 200 in the form of a comb, made from a second material, on the metal bonding layer 300, by additive manufacturing, preferably by SLS or PBF,
c) removing the substrate 100 and cutting the bonding layer 300 to the size of the second end of the arms, by means of which a comb 200 having arms metallised by a metal layer 300 is obtained.

The same method is used for manufacturing another comb made from a material with a conductivity opposite to the first comb. The two combs are next assembled.

According to a sixth embodiment shown in FIG. 6A to 6D, the method comprises the following steps:
providing a substrate 100 made from a first material, locally covered with a metal layer 300, so as to form metal islands,
b) depositing a thermoelectric pin 200 made from a second material on each metal island covering the substrate 100, by additive manufacturing, preferably by SLS or PBF, and then a metallisation layer 400 and another thermoelectric element 500 made from another thermoelectric material,
c) removing the substrate 100, by means of which a thermoelectric structure, which comprises a metal layer 300 covered by a first thermoelectric pin 200, a metallisation layer 400 and then a second thermoelectric pin 500, is obtained.

This embodiment is particularly advantageous for manufacturing segmented thermoelectric pins.

1. A method for manufacturing a thermoelectric structure comprising the following steps:
a) providing a substrate, covered completely or locally with a metal layer,
b) forming a thermoelectric element made from a thermoelectric material on the metal layer, by additive manufacturing, preferably by selective laser sintering or by powder bed laser fusion,
wherein the method includes a subsequent step c) during which the substrate is removed to obtain a thermoelectric structure comprising the metal layer and the thermoelectric element.

2. The method according to claim 1, wherein the thermoelectric element is a pin, having a base and a height.

3. The method according to claim 1, wherein the metal layer has the same surface area as the surface area of the base of the pin.

4. The method according to claim 1, wherein the metal layer has a surface area greater than the surface area of the base of the pin.

5. The method according to claim 1, wherein, in step a), the metal layer locally covers the substrate so as to form a plurality of islands and in that a thermoelectric element or a plurality of thermoelectric elements are deposited on each island during step b).

6. The method according to claim 1, wherein the thermoelectric element is a part in the form of a comb delimiting a base and a plurality of arms, substantially parallel to each other, extending substantially orthogonally from the base, the plurality of arms having a first end and a second end, the first end being connected to the base, and the second end of the plurality of arms being in contact with the metal layer.

7. The method according to claim 1, wherein the thermoelectric material is selected from Si, SiGe, Bi₂Te₃, Half-Heusler and Skutterudites.

8. The method according to, wherein the substrate is 316L steel, aluminium, titanium, a CuZr alloy, a ceramic or graphite.

9. The method according to claim 1, wherein the metal layer is made from a material selected from Al, Ti, Cu, Au and Ni.
